(19) United States
(12) Patent Application Publication
(10) Pub. No.: US 2004/0245590 A1
(43) Pub. Date: Dec. 9, 2004

(54) Image sensor package

(76) Inventors: Jackson Hsieh, Hsinchu Hsien (TW); Jichen Wu, Hsinchu Hsien (TW); Eric Chang, Hsinchu Hsien (TW); Bruce Chen, Hsinchu Hsien (TW)

Correspondence Address: PRO-TECHTOR INTERNATIONAL, 20775 Norada Court, Saratoga, CA, 95070-3018, US

(21) Appl. No.: 10/456,012

(22) Filed: Jun. 5, 2003

(51) Int. Cl. H01L 31/0203

(52) U.S. Cl. 257/433

(57) ABSTRACT

An image sensor package includes a plurality of leadframes, a molded resin, a photosensitive, a plurality of wires and a transparent layer. Each of the leadframes have a first board and a second board located on a height different from that of the first board, and a chamber is defined upper a central of the plurality of leadframes. The molded resin is for encapsulating the leadframes, and is forming an upper surface and a lower surface, wherein the first boards of the leadframes are exposed from the upper surface of the molded resin. The photosensitive chip is mounted onto the upper surface of the molded resin and arranged within the chamber. Each of wires are electrically connected the photosensitive chip to the each second board of the plurality of leadframes. And the transparent resin is covered onto the each first board of the plurality of leadframes.

### BACKGROUND OF THE INVENTION

1. Field of the Invention

The present invention relates to an image sensor package, and more particularly to a photosensitive chip package having a reduced manufacturing cost and package volume.

2. Description of the Related Art

Referring to FIG. 1, a conventional image sensor includes a plurality of leadframes 10, a frame layer 16, a photosensitive chip 18, wires 19 and a transparent layer 22. The plurality of leadframes 10 arranged in matrix, each of the leadframes 10 having a first board 12 and a second board 14 located on a height different from the second board 14. The frame layer 16 for encapsulating the leadframes 10, and a chamber 20 being defined for mounting the photosensitive chip, wherein the first board 12 and second board 14 are exposed from the frame layer 16. The photosensitive chip 18 is arranged within the chamber 20. The wire 19 are for electrically connecting the photosensitive chip 18 to the second board 14 of the leadframes. The transparent layer 22 is disposed on the upper surface of the frame layer 16. Furthermore, the photosensitive chip 18 may receive optical signals passing through the transparent layer 22.

According to the above-mentioned structure, the present invention has following advantage.

1. The transparent layer 22 is disposed on the upper surface of the frame

### SUMMARY OF THE INVENTION

An object of the present invention is to provide an image sensor package, which may be advantageously reduced the volume of the package.

Another object of the present invention is to provide an image sensor package, which may be assembled easily and has a reduced manufacturing cost.

To achieve the above-mentioned object, the present invent of an image sensor package includes a plurality of leadframes, a molded resin, a photosensitive, a plurality of wires and a transparent layer. Each of the leadframes have a first board and a second board located on a height different from that of the first board, and a chamber is defined upper a central of the plurality of leadframes. The molded resin is for encapsulating the leadframes, and is forming an upper surface and a lower surface, wherein the first boards of the leadframes are exposed from the upper surface of the molded resin. The photosensitive chip is mounted onto the upper surface of the molded resin and is arranged within the chamber. Each of wires are electrically connected the photosensitive chip to the each second board of the plurality of leadframes. And the transparent resin is covered onto the each first board of the plurality of leadframes.

Furthermore, the transparent resin of the image sensor may be mount on the first board of the leadframes, the package may advantageously reduced the volume of the package, and may be assembled easily and has a reduced manufacturing cost.

### BRIEF DESCRIPTION OF THE DRAWINGS

FIG. 1 is a schematic illustration showing a conventional image sensor package.

FIG. 2 is a cross-sectional view showing an image sensor package of the present invention.

FIG. 3 is a schematic illustration showing an image sensor of the present invention.

### DETAILED DESCRIPTION OF THE INVENTION

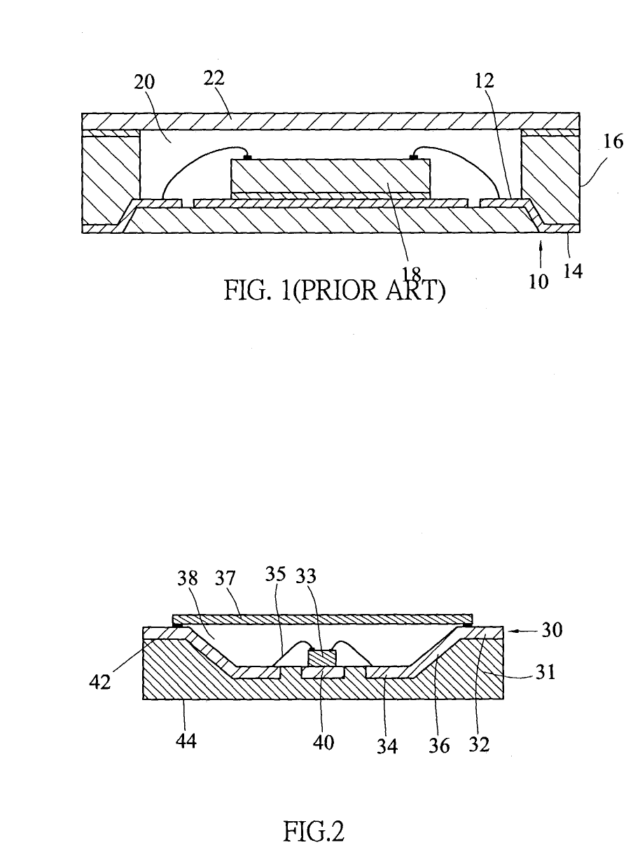

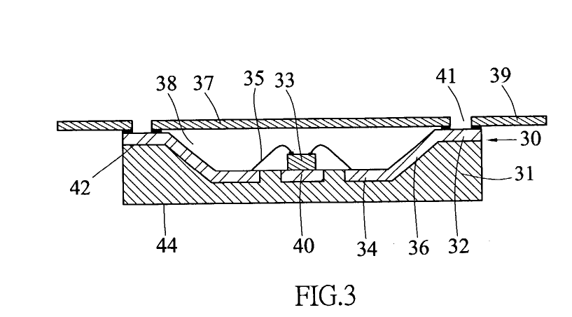

Referring to FIG. 2, an image sensor package of the present invention includes a plurality of leadframes 30, a molded resin 31, a photosensitive chip 33, a plurality of wires 35, and a transparent layer 37

The plurality of leadframes 30 are arranged in matrix, each of leadframes 30 have a first board 32 and a second board 34 located on a height different from that of the first board 32, a chamber 38 is defined upper a central of the leadframe 30, and a middle board 40 is arranged within the internal of the chamber 38.

The molded resin 31 is made of industrial plastic by way of injection molding to encapsulate leadframes 30, and has a upper surface 42 and a lower surface 44. Wherein the upper surface of the first boards 32 of the leadframes 30 are exposed from the upper surface 42 of the molded resin 31, the upper surface of the second board 34 of the leadframes 30 are exposed from the upper surface 42 of the molded resin 31.

The photosensitive chip 33 is mounted onto the middle board 40 of the leadframe 30 and is arranged within the chamber 38.

Each of wires 35 are electrically connected the photosensitive chip 33 to the each second board 34 of the plurality of leadframes 30.and

The transparent resin 37 is covered onto the each first board 32 of the plurality of leadframes 30, therefore, the photosensitive chip 33 may be received optical signals passing through the transparent resin 37.

Please referring to GIG.3, a schematic illustrate showing an image sensor package of the present invention. Wherein a printed circuit board 39 is provided, the printed circuit board 39 is formed with a through hole 41, which is larger than the transparent resin 37. The printed circuit board 39 is covered over the first board 32 of the leadframes 30, and is electrically connected the first board 32 of the leadframes 30. Then, the photosensitive chip 33 may be received optical signals passing through the transparent layer 37 and through hole 41 of the printed circuit board 39, therefore, the signals from the photosensitive chip 33 may be transmitted to the printed circuit board 39 via the first board 32 of the leadframe 30.

To sum up, the present invention has the following advantages.

1. Since the leadframes 30 are formed with a chamber 38, and the photosensitive chip 33 is located within the chamber 38 so as to the volume the package can be reduced.

2. Since the printed circuit board 39 is directly covered over the first board 32 of the leadframes 30, on frame layer has to be provided. Thus, the manufacturing processes may be simplified and manufacturing cost may be reduced.

Wherein the second board 34 and middle board 40 of the leadframes 30 are exposed from the lower surface 44 of the molded layer 31, therefore, the lower surface of second board 34 may be electrically connected to a printed electric board, thus, the photosensitive chip 43 may enhance the effects of dissipation head

While present the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. An image sensor package for being electrically connected to a printed circuit board, the printed circuit board having a through hole, the image sensor package comprising:
a plurality of leadframes arranged in a matrix, each of the leadframes having a first board and a second board located on a height different from that of the first board, and a chamber being defined upper a central of said a plurality of leadframes;
a molded resin for encapsulating the leadframes and forming a upper surface and a lower surface, wherein the first boards of the leadframes being exposed from the upper surface of the molded resin, the second board of the leadframes being exposed from the upper surface of the molded resin;
a photosensitive chip mounted onto the upper surface of the molded resin and arranged within the chamber;
a plurality of wires being electrically connected the photosensitive chip to the each second board of the plurality of leadframes; and
a transparent resin covered onto the each first board of the plurality of leadframes, therefore, the photosensitive chip may received optical signals passing through the transparent resin.

2. The image sensor package according to claim 1, further comprising a middle board is arranged within the chamber of the leadframes, wherein the photosensitive chip is placed on the middle board.

3. The image sensor package according to claim 1, wherein the molded resin is formed from industrial material by way of injecting molding, for encapsulating the plurality of the leadframes.
